(19) United States
(12) Patent Application Publication
(10) Pub. No.: US 2012/0038384 A1
(43) Pub. Date: Feb. 16, 2012

(54) PROBE BOARD AND METHOD OF MANUFACTURING THE SAME

(75) Inventor: Yong Seok CHOI, Suwon (KR)

(73) Assignee: SAMSUNG ELECTRO-MECHANICS CO., LTD.

(21) Appl. No.: 13/013,335

(22) Filed: Jan. 25, 2011

(30) Foreign Application Priority Data
Aug. 13, 2010 (KR) 10-2010-0078496

(51) Int. Cl. G01R 31/00; H05K 13/00

(52) U.S. Cl. 324/756.03; 29/829

(57) ABSTRACT

There are provided a probe board and a method of manufacturing the same. The probe board includes a ceramic substrate having an uneven portion in one surface thereof, one or more electrode pads placed on the uneven portion, and a buffer portion placed along an outer circumferential surface of each of the electrode pads, the buffer portion being formed by melting the ceramic substrate.

### CROSS-REFERENCE TO RELATED APPLICATIONS

This application claims the priority of Korean Patent Application No. 10-2010-0078496 filed on Aug. 13, 2010, in the Korean Intellectual Property Office, the disclosure of which is incorporated herein by reference.

### BACKGROUND OF THE INVENTION

1. Field of the Invention

The present invention relates to a probe board and a method of manufacturing the same, and more particularly, to a probe board, capable of ensuring the firm fixation of electrode pads and the enhanced strength of a ceramic substrate, and a method of manufacturing the same.

2. Description of the Related Art

In general, an integrated circuit, placed on a wafer or the like, needs to be tested with respect to the electrical characteristics thereof in order to determine whether or not the integrated circuit is defective. Only good-quality integrated circuits are selected and subsequently subjected to a packaging process. After the packaging process, the integrated circuits undergo another electrical property test and it is thus finally determined as to whether the integrated circuits are defective or not. In such a manner, the yield of complete products is improved.

In other words, integrated circuits need to go through a plurality of electrical property tests so as to be confirmed to be normal. Such tests on integrated circuits involve the use of a probe card having a plurality of probes to measure electrical properties of integrated circuits by using contact between the probes and the integrated circuits.

In detail, chips on wafers are determined to be defective or non-defective, based on a probing test, and chips that have been determined to be non-defective are packaged and released. As for the probing test, a test device applies a predetermined electrical signal to a chip on a wafer through a probe provided in a probe card. Thereafter, the test device receives an electrical signal in response to the applied predetermined electrical signal to thereby determine whether or not the chip configured on the wafer is normal.

As a demand for high-density chips has recently been increased, circuit patterns and circuit pads connected to the circuit patterns on wafers are arranged at an extremely high density. In this respect, the contact pads are made to have a sufficiently small size, and adjacent contact pads are arranged at very small intervals therebetween. For this reason, probes in a probe card, coming into contact with the contact pads in a test process, need to be arranged at sufficiently small intervals to correspond with the contact pads. Moreover, electrode pads in the probe board including the probes also need to be formed to be fine.

### SUMMARY OF THE INVENTION

An aspect of the present invention provides a probe board, capable of ensuring the firm fixation of electrode pads and the enhanced strength of a ceramic substrate, and a method of manufacturing the same.

According to an aspect of the present invention, there is provided a probe board including: a ceramic substrate having an uneven portion in one surface thereof; one or more electrode pads placed on the uneven portion; and a buffer portion placed along an outer circumferential surface of each of the electrode pads, the buffer portion being formed by melting the ceramic substrate.

The uneven portion may be formed in a part of the one surface of the ceramic substrate.

The uneven portion may be formed in the entirety of the one surface of the ceramic substrate.

The uneven portion of the ceramic substrate on which the electrode pads are not placed may be removed by melting the ceramic substrate.

The ceramic substrate may be a low-temperature co-fired ceramic substrate.

The electrode pads may be formed by using metallic-paste or by thin-film deposition.

The buffer portion may be formed by a laser emission.

According to another aspect of the present invention, there is provided a method of manufacturing a probe board, the method including: preparing a ceramic substrate; forming an uneven portion in one surface of the ceramic substrate; forming one or more electrode pads on the uneven portion; and forming a buffer portion along an outer circumferential surface of each of the electrode pads by melting the ceramic substrate.

The forming of the uneven portion may be performed upon a part of the one surface of the ceramic substrate.

The forming of the uneven portion is performed upon the entirety of the one surface of the ceramic substrate.

The forming of the one or more electrode pads may be performed by a metallic-paste printing process or a thin-film deposition process.

The ceramic substrate may be prepared by a low-temperature co-fired ceramic process.

The forming of the buffer portion may be performed by a laser emission.

The method may further include removing the uneven portion of the ceramic substrate on which the electrode pads are not formed, by melting the ceramic substrate.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a schematic cross-sectional view illustrating a probe card including a probe board according to an exemplary embodiment of the present invention;

FIG. 2A is a schematic cross-sectional view illustrating a probe board according to an exemplary embodiment of the present invention;

FIG. 2B is an enlarged cross-sectional view illustrating one area of the probe board depicted in FIG. 2A;

FIG. 2C is a top plan view illustrating one surface of the probe board depicted in FIG. 2A; and

FIGS. 3A through 3C are cross-sectional views illustrating a method of manufacturing a probe board according to an exemplary embodiment of the present invention.

### DETAILED DESCRIPTION OF THE PREFERRED EMBODIMENT

Exemplary embodiments of the present invention will now be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the shapes and dimensions of element may be exaggerated for clarity. Like reference numerals in the drawings denote like elements.

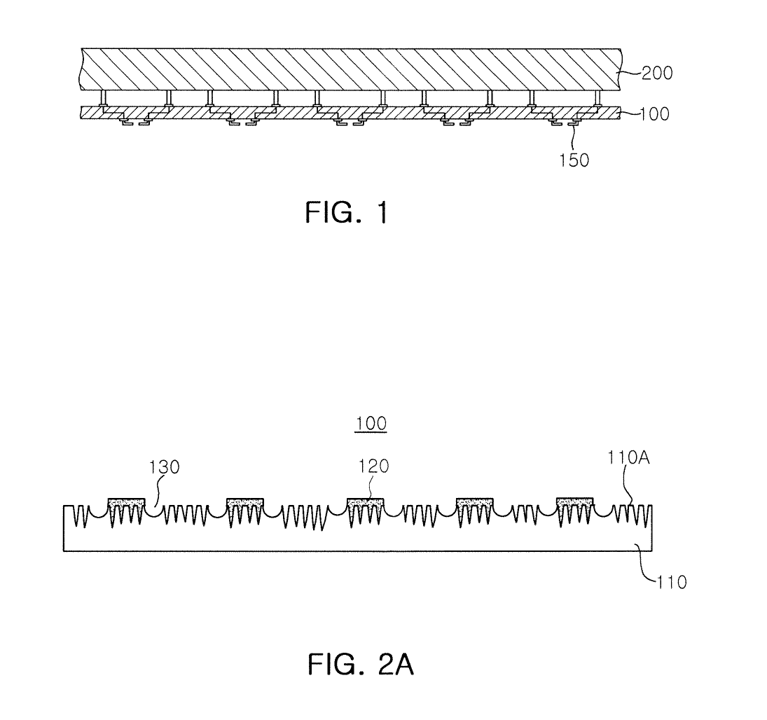

FIG. 1 is a schematic cross-sectional view illustrating a probe card including a probe board according to an exemplary embodiment of the present invention.

Referring to FIG. 1, a probe card includes a performance board 200, a probe board 100, and probes 150.

The performance board 200 may be configured in the form of a circular plate, and have top and bottom surfaces. Circuit patterns (not shown) for a test process are formed on the top surface of the performance board 200, while interposers may be mounted on the bottom surface thereof. The interposers are connected with the probe board 100.

A predetermined electrical signal is transmitted to the probe board 100 through the performance board 200 from a test device.

The probes 150 formed on the probe board 100 come into contact with contact pads on a wafer. The predetermined electrical signal, transmitted through the performance board 200, is sent to the contact pads on the wafer and subsequently returns to the test device. In such a manner, it is determined as to whether a chip configured on the wafer is normal or not.

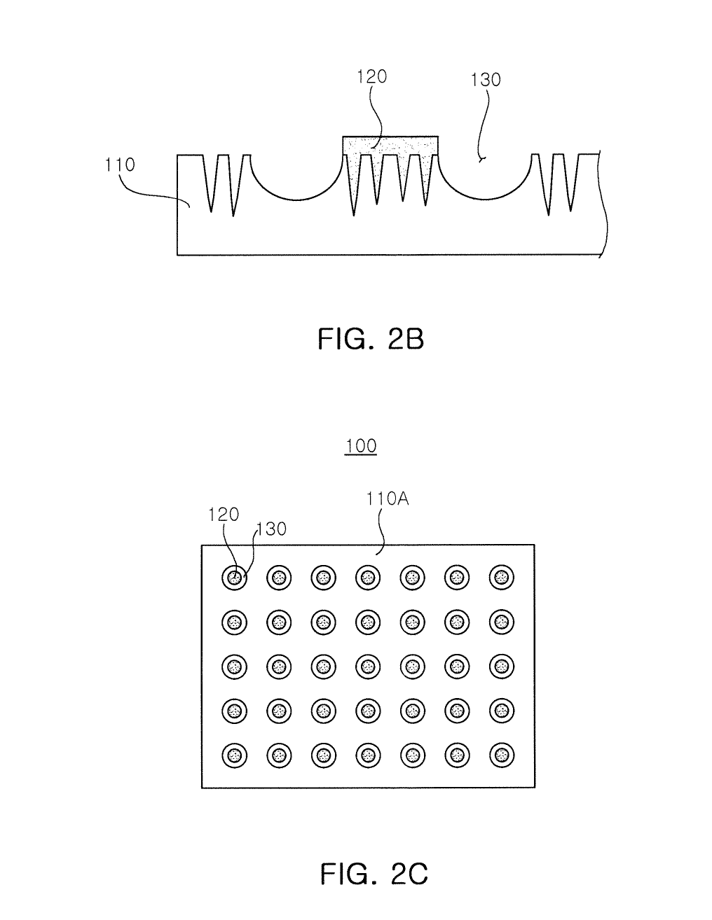

FIG. 2A is a schematic cross-sectional view illustrating the probe board 100 according to an exemplary embodiment of the present invention. FIG. 2B is an enlarged cross-sectional view illustrating one area of the probe board 100 depicted in FIG. 2A. FIG. 2C is a top plan view illustrating one surface of the probe board 100 depicted in FIG. 2A.

Referring to FIGS. 2A through 2C, the probe board 100, according this exemplary embodiment of the invention, includes a ceramic substrate 110, electrode pads 120 disposed on one surface 110A of the ceramic substrate 110, and buffer portions 130 formed along the respective outer circumferential surfaces of the electrode pads 120.

The ceramic substrate 110 may be a stack of a plurality of ceramic layers. The ceramic layers may have inner circuit patterns and via electrodes connecting the inner circuit patterns.

The one surface 110A of the ceramic substrate 110 may be formed to be uneven in part or in entirety. That is, the one surface 110A of the ceramic substrate 110 may have an uneven portion.

If the uneven portion is formed in only part of the one surface 110A of the ceramic substrate 110, the electrode pads 120 may be formed within the part of the one surface 110A in which the uneven portion is positioned.

Alternatively, the uneven portion may be formed in the entirety of the one surface 110A of the ceramic substrate 110, for the ease of processing.

The uneven portion may be provided by the erosion of the ceramic substrate 110.

One or more electrode pads 120 maybe formed on the one surface 110A of the ceramic substrate 110. Here, the one or more electrode pads 120 are electrically connected with the inner circuit patterns of the ceramic substrate 110. Probes may be formed on the electrode pads 120.

The electrode pads 120 may be disposed on the uneven portion in the one surface 110A of the ceramic substrate 110. As the electrode pads 120 are formed on the uneven portion, the electrode pads 120 contact the ceramic substrate 110 with a significantly large contact area, thereby ensuring the firm fixation thereof, namely, enhancing the fixation force thereof to the ceramic substrate 110.

The ceramic substrate 110 may be a Low Temperature Co-fired Ceramic (LTCC) substrate.

As for a High Temperature Co-fired Ceramic (HTCC) substrate), firing is carried out at a temperature of about 1500° C. to 1700° C., and therefore, W, Mo or the like needs to be used as a conductive material, resulting in high processing costs and difficulties in implementing size precision in fine patterns over a large area. Meanwhile, a related-art LTCC substrate provides lower fixation force to a thin film electrode than the HTCC substrate, and thus the use of thereof is limited.

However, according to this exemplary embodiment of the invention, the uneven portion formed on the ceramic substrate 110 contributes to enhancing the fixation force of the electrode pads. For this reason, the LTCC ceramic substrate may be used as the ceramic substrate 110.

The electrode pads 120 may be formed by using metallic paste. A metal of the metallic paste may utilize Ag, Au, Pd, Pt, Rh, Cu, Ti, W, Mo, Ni or an alloy thereof. The electrode pad 120 may be formed by printing the metallic paste and then sintering the resultant structure.

Alternatively, the electrode pad 120 may be formed by a thin film deposition process, for example, sputtering deposition.

In addition, the electrode pad 120 may be configured to have a multilayer structure, for example, Ti/Cu/Au. Here, the Au layer may be formed by plating.

According to this exemplary embodiment, buffer portions 130 may be formed along the respective outer circumferential surfaces of the electrode pads 120.

The buffer portions 130 are formed by melting the ceramic substrate 110, and may be formed by emitting a laser beam to the ceramic substrate 110 along the outer circumferential surfaces of the electrode pads 120.

As for the probe board according to this exemplary embodiment, the uneven portion is formed in one surface of the ceramic substrate 110 in order to enhance the fixation force with the electrode pads 120. However, this uneven portion may deteriorate the strength of the ceramic substrate 110.

Particularly, the uneven portion positioned at the outer circumferential surfaces of the electrode pads may cause cracks, impairing the strength of the ceramic substrate 110.

According to this exemplary embodiment, heat is applied to the outer circumferential surfaces of the electrode pads 120 to thereby melt glass components of the ceramic substrate 110. In such a manner, part of the uneven portion is removed and the buffer portions 130 are formed accordingly. This removal of the part, which may cause cracks, may lead to an increase in the strength of the ceramic substrate 110, as well as an increase in the fixation force of the electrode pads.

Alternatively, similarly to the formation of the buffer portion, the uneven portion may be removed by applying heat to a region of the ceramic substrate 110 in which the electrode pads are absent, namely, are not placed.

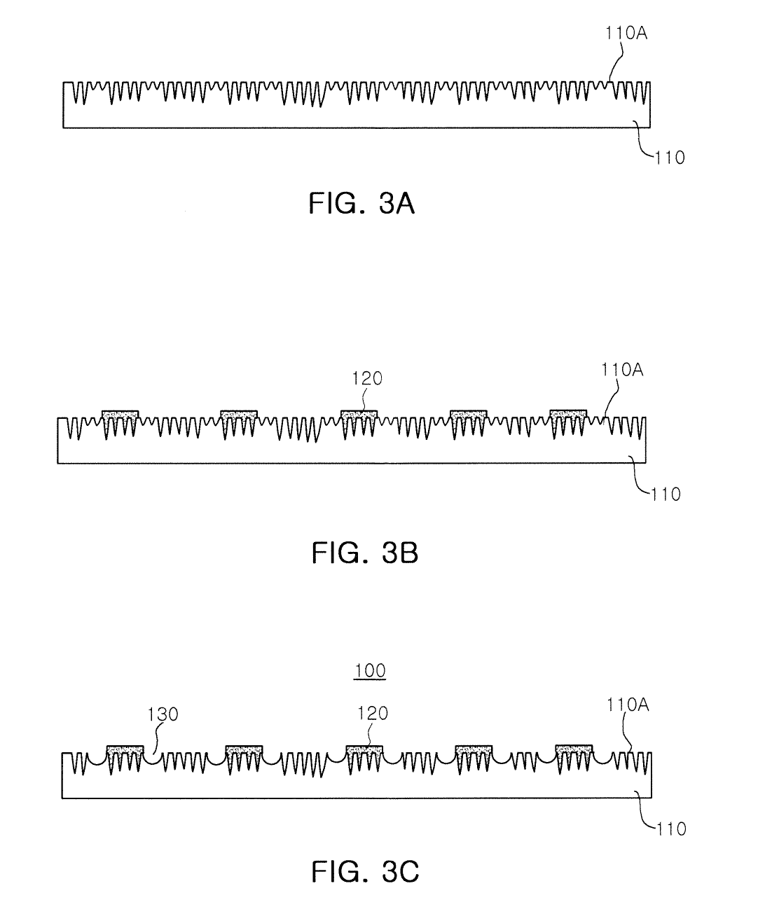

Hereinafter, a method of manufacturing a probe board, according to an exemplary embodiment of the present invention, will be explained. FIGS. 3A through 3C are cross-sectional views illustrating a method of manufacturing a probe board according to an exemplary embodiment of the present invention.

First, as shown in FIG. 3A, a plurality of ceramic layers are stacked and sintered to thereby provide a body of the ceramic substrate 110.

The plurality of ceramic layers constituting the body of the ceramic substrate 110 may include inner circuit patterns and via electrodes connecting the inner circuit patterns.

The ceramic substrate 110 may be an LTCC substrate. An LTCC ceramic substrate may be formed by preparing ceramic green sheets using a known method such as a doctor blade process, forming conductive vias and inner circuit patterns in the ceramic green sheets, stacking the ceramic green sheets, and sintering the resultant stack. The sintering may be performed at a temperature ranging from about 700 to 900° C.

Subsequently, an uneven portion is formed in one surface 110A of the ceramic substrate 110. The method of forming the uneven portion is not specifically limited, and a chemical etching method may be used for example. When the chemical etching is performed, glass components of the ceramic substrate 110 are melted and thus erosion occurs therein, thereby forming the uneven portion. The uneven portion enlarges the surface area of the ceramic substrate 110 and thus enhances the fixation force between the ceramic substrate 110 and electrode pads when the electrode pads are formed.

The uneven portion may be formed only in part of the one surface 110A of the ceramic substrate 110. In this case, in the subsequent process, the electrode pads may be formed in the part of the one surface 110A in which the uneven portion is formed.

In this case, a mask having openings with a predetermined pattern is placed on the one surface 110A of the ceramic substrate 110, and chemical etching is performed thereupon, thereby forming the uneven portion only in the part of the one surface 110A.

Alternatively, for ease of processing, the mask may not be used, and the uneven portion may be formed over the entirety of the one surface 110A of the ceramic substrate 110.

Subsequently, as shown in FIG. 3B, one or more electrode pads 120 are formed on the one surface 110A of the ceramic substrate 110. The electrode pads 120 may be formed to be electrically connected with the inner circuit patterns of the ceramic substrate 110.

The method of forming the electrode pads 120 is not specifically limited. The electrode pads 120 may be formed by using metallic paste for example. To form the electrode pads 120, the metallic paste may be printed by using a screen printing method or the like and is then sintered.

Alternatively, the electrode pads 120 may be formed by using a thin film deposition process such as sputtering deposition.

Subsequently, as shown in FIG. 3C, buffer portions 130 are formed along the outer circumferential surfaces of the electrode pads 120, respectively.

The buffer portions 130 may be formed by melting the ceramic substrate 110. The method of melting the ceramic substrate 110 is not specifically limited. For example, the melting may be carried out by using heat from laser beams emitted to the ceramic substrate 110.

When heat is applied to the ceramic substrate 110, glass components of the ceramic substrate 110 are melted, and part of the uneven portion is removed, thereby forming the buffer portions 130.

The uneven portion on the one surface of the ceramic substrate 110 on which no electrode pads are formed may be removed.

As set forth above, according to exemplary embodiments of the invention, an uneven portion is formed in one surface of a body of a ceramic substrate, and thus electrode pads contact a ceramic substrate with an increased contact area due to the uneven portion, thereby enhancing the fixation force thereof.

Furthermore, buffer portions are formed around the respective outer circumferential surfaces of the electrode pads by removing the uneven portion, thereby eliminating the cause of cracks. Accordingly, the strength of the ceramic substrate, as well as the fixation force of electrodes, can be enhanced.

While the present invention has been shown and described in connection with the exemplary embodiments, it will be apparent to those skilled in the art that modifications and variations can be made without departing from the spirit and scope of the invention as defined by the appended claims.

What is claimed is:

1. A probe board comprising:
a ceramic substrate having an uneven portion in one surface thereof;
one or more electrode pads placed on the uneven portion; and
a buffer portion placed along an outer circumferential surface of each of the electrode pads, the buffer portion being formed by melting the ceramic substrate.

2. The probe board of claim 1, wherein the uneven portion is formed in a part of the one surface of the ceramic substrate.

3. The probe board of claim 1, wherein the uneven portion is formed in an entirety of the one surface of the ceramic substrate.

4. The probe board of claim 1, wherein the uneven portion of the ceramic substrate on which the electrode pads are not placed is removed by melting the ceramic substrate.

5. The probe board of claim 1, wherein the ceramic substrate is a low-temperature co-fired ceramic substrate.

6. The probe board of claim 1, wherein the electrode pads are formed by using metallic paste or by thin-film deposition.

7. The probe board of claim 1, wherein the buffer portion is formed by a laser emission.

8. A method of manufacturing a probe board, the method comprising:
preparing a ceramic substrate;
forming an uneven portion in one surface of the ceramic substrate;
forming one or more electrode pads on the uneven portion; and
forming a buffer portion along an outer circumferential surface of each of the electrode pads by melting the ceramic substrate.

9. The method of claim 8, wherein the forming of the uneven portion is performed upon a part of the one surface of the ceramic substrate.

10. The method of claim 8, wherein the forming of the uneven portion is performed upon an entirety of the one surface of the ceramic substrate.

11. The method of claim 8, wherein the forming of the one or more electrode pads is performed by a metallic-paste printing process or a thin-film deposition process.

12. The method of claim 8, wherein the ceramic substrate is prepared by a low-temperature co-fired ceramic process.

13. The method of claim 8, wherein the forming of the buffer portion is performed by a laser emission.

14. The method of claim 8, further comprising removing the uneven portion of the ceramic substrate on which the electrode pads are not formed, by melting the ceramic substrate.
